(19) United States
(12) Patent Application Publication
(10) Pub. No.: US 2008/0160743 A1
(43) Pub. Date: Jul. 3, 2008

(54) COMPOSITION FOR CLEANING SUBSTRATES AND METHOD OF FORMING GATE USING THE COMPOSITION

(75) Inventors: Hyo-san LEE, Suwon-si (KR); Sang-yong KIM, Yongin-si (KR); Chang-ki HONG, Seongnam-si (KR); Woo-gwan SHIM, Yongin-si (KR); Jeong-nam HAN, Seoul (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 11/941,178

(22) Filed: Nov. 16, 2007

Related U.S. Application Data
(62) Division of application No. 11/444,416, filed on Jun. 1, 2006.

(30) Foreign Application Priority Data
Sep. 5, 2005 (KR) 10-2005-0082450

(51) Int. Cl. H01L 21/283

(52) U.S. Cl. 438/591; 257/E21.209

(57) ABSTRACT

Provided are a substrate cleaning composition including a fluoride compound, an inorganic acid, and deionized water, and a method of forming a gate using the same. The fluoride compound is one of HF, NH₄F, and a combination thereof, and the inorganic acid is one of HNO₃, HCl, HCIO₄, H₂SO₄, or H₅IO₆. The substrate cleaning composition removes polymer by-products generated by etching a metal layer for forming a gate, but not other layers.

### CROSS-REFERENCE TO RELATED APPLICATION

This is a divisional of application Ser. No. 11/444,416, filed Jun. 1, 2006, which is incorporated herein by reference in its entirety.

### BACKGROUND OF THE INVENTION

1. Field of the Invention

Embodiments of the invention relate to a method of manufacture of semiconductor devices. More particularly, embodiments of the invention relate to a method adapted to clean by-products generated when a metal layer is etched during the formation of a metal gate structure.

2. Description of the Related Art

As the integration density of constituent elements in contemporary semiconductor memory devices has increased over recent years, the allocated area for individual memory cells has fallen proportionally. This shrinking availability of allocated area on a semiconductor substrate and the corresponding reductions in memory cell size have become a very real barrier to further increases in integration density.

This is particularly true for cell transistors adapted for use in nonvolatile memory devices. For example, conventional materials once used to form the gate structure of cell transistors have proved inadequate for increasingly small cell transistors. Thus, new material compositions and structures have been proposed, including silicon-oxide-nitride-oxide-silicon (SONOS) type nonvolatile memory devices having a single gate electrode like a metal-oxide semiconductor field effect transistor (MOSFET) structure adapted to trap charge. SONOS type nonvolatile memory devices have the advantages of a simple manufacturing process and an easy connection with peripheral regions and/or logic regions of an integrated circuit. Charge trap flash devices (CTF) have also been proposed. These devices include metal layers having high work functions and charge protecting layers as gate electrodes. The use of high K dielectric layers to increase the performance of an inactive memory device has also been proposed.

In one conventional embodiment, tantalum-aluminum oxide-nitride-oxide-silicon (TANOS) type nonvolatile memory devices have been proposed. These devices use TaN layers for the gate electrode and aluminum oxide layers for high K dielectric layers. In order to manufacture these devices, the metal layer (e.g., the TaN layer) must be etched. Unfortunately, the etching of the metal layer results in the abundant generation of by-products, such as hard polymers.

Conventional substrate cleaning compositions adapted to the removal of hard polymers include such brands commercially known as EKC™, NE200™, etc. However, these conventional substrate cleaning compositions are organic solutions, and as such, are ill suited to the cleaning of hard polymers comprising metal components.

Of further note, conventional cleaning solutions are often applied in aerosol form to a subject substrate. However, emerging analysis suggests that aerosol application tends to damage the lower layers on the substrate due to the physical impact of the applied solution. Aerosol application is also a relatively complicated process.

### SUMMARY OF THE INVENTION

Embodiments of the invention provide a substrate cleaning composition adapted to more effectively remove polymer by-products generated by the etching of a metal layer. Embodiments of the invention also provide a method of forming a gate structure having favorable electric characteristics using a substrate cleaning composition adapted to effectively remove polymer by-products.

Thus, in one example, the invention provides a substrate cleaning composition comprising; a fluoride compound, an inorganic acid, and deionized water.

The fluoride compound may comprise at least one of HF, and NH₄F. The concentration of the fluoride compound may range between about 0.001 and 10.0 wt %, based on the total weight of the substrate cleaning composition.

The inorganic acid may comprise at least one selected from a group consisting of HNO₃, HCl, HCIO₄, H₂SO₄, and H₅IO₆. The concentration of the inorganic acid may range between about 3 and 20 wt % based on the total weight of the substrate cleaning composition.

The substrate cleaning composition may further comprise an organic acid, such as any one or more of acetic acid, palmitic acid, oxalic acid, and tartaric acid. The concentration of the organic acid may range up to not more than 50 wt % based on the total weight of the substrate cleaning composition.

The substrate cleaning composition may further comprise a surfactant. The surfactant may comprise an ethylene oxide-based compound of which both end groups are hydroxide groups, such as any one or more of ethylene glycol, propylene glycol, ethylene oxide, monoethylene glycol, diethylene glycol, triethylene glycol, propylene oxide, 1,2-propylene glycol, dipropylene glycol, tripropylene glycol, and 1,2-butylene oxide.

The substrate cleaning composition may further comprise a chelating agent, such as an amine-based compound including a C₁ to C₁₀ alkyl group, monoethanolamine, diethanolamine, triethanolamine, diethylenetriamine, an amine carboxylic acid ligand, and an amino acid. The amino acid may comprise one or more of glycine, alanine, valine, leucine, isoleucine, serine, threonine, tyrosine, phenylalanine, tryptophane, methionine, cystine, proline, sulphamin acid, and hydroxyproline.

In another embodiment, the invention provides a method of forming a gate structure adapted for use in a semiconductor device, the method comprising; forming a metal layer, forming a hard mask on the metal layer, etching the metal layer using the hard mask as an etch mask, and cleaning the resultant structure with a substrate cleaning composition comprising a fluoride compound, an inorganic acid, and deionized water.

### DETAILED DESCRIPTION OF DRAWINGS

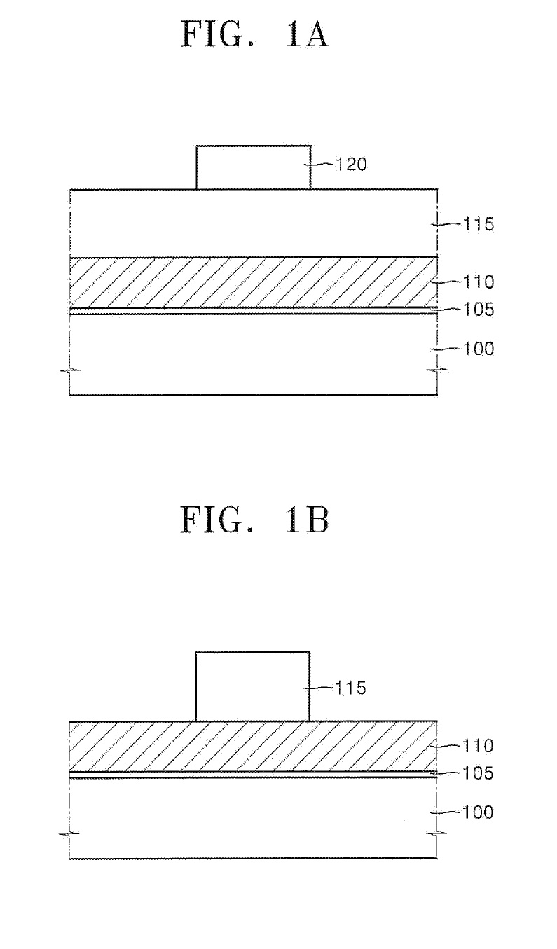

FIGS. 1A through 1D are cross-sectional views illustrating a method of forming a gate structure according to an embodiment of the invention;

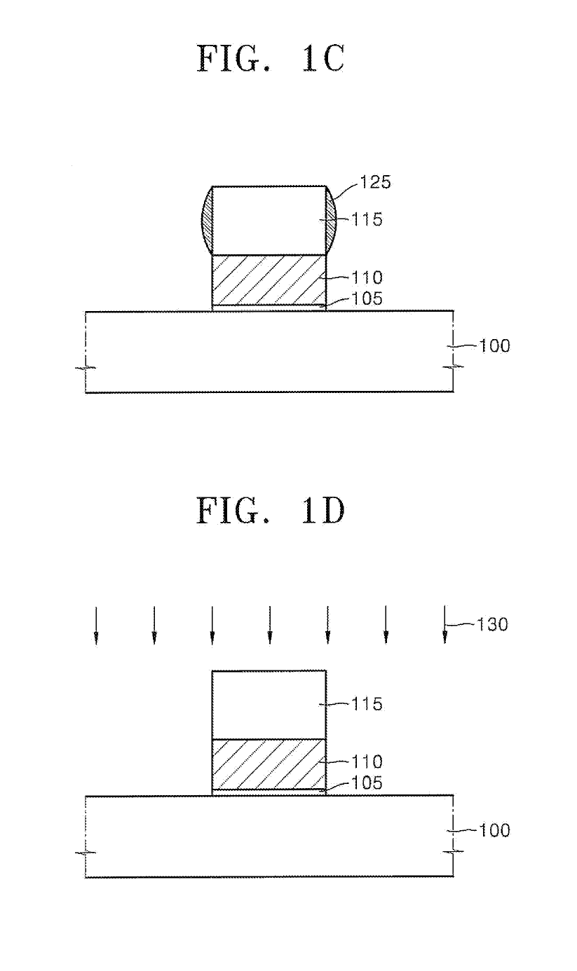

FIGS. 2A through 2D are cross-sectional views illustrating a method of forming a gate structure according to another embodiment of the invention;

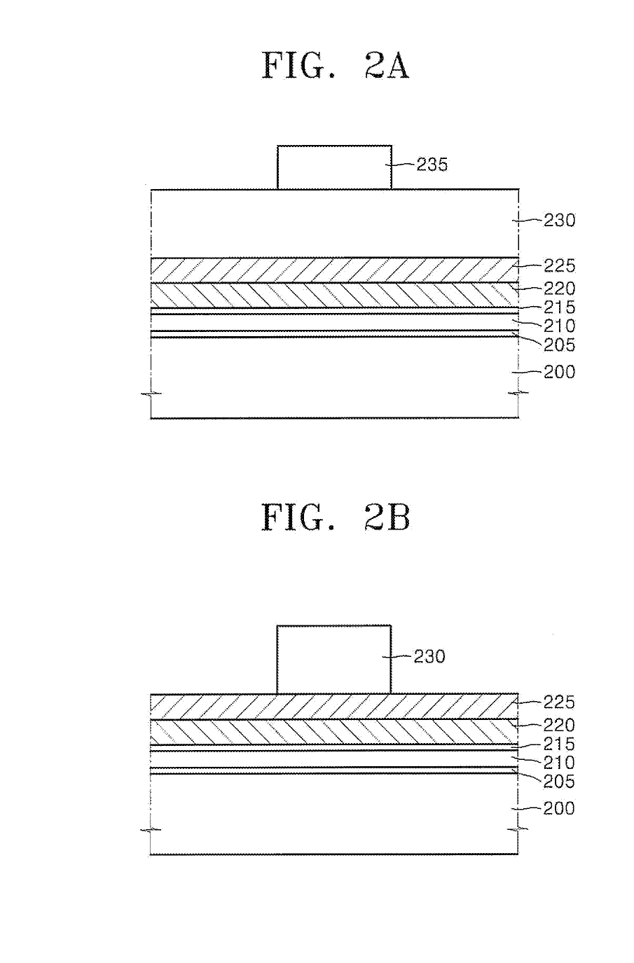

FIG. 3 is a scanning electron microscope (SEM) image showing a gate structure after cleaning with a conventional substrate cleaning composition;

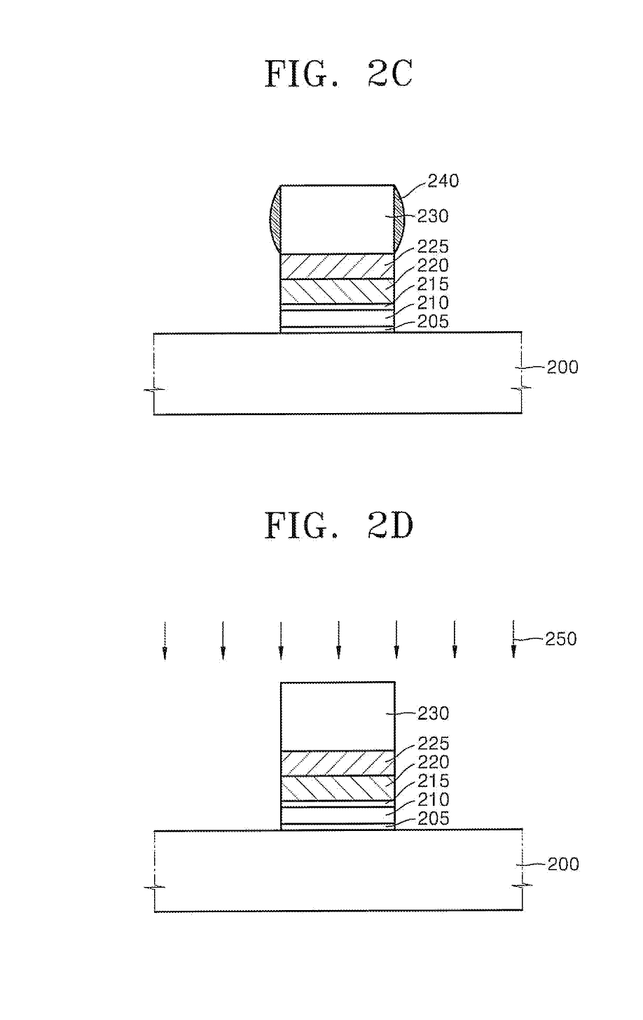

FIG. 4 is a graph of an energy dispersive X-ray spectroscopy (EDXS) further illustrating the composition of the polymer by-product described with reference to FIG. 3;

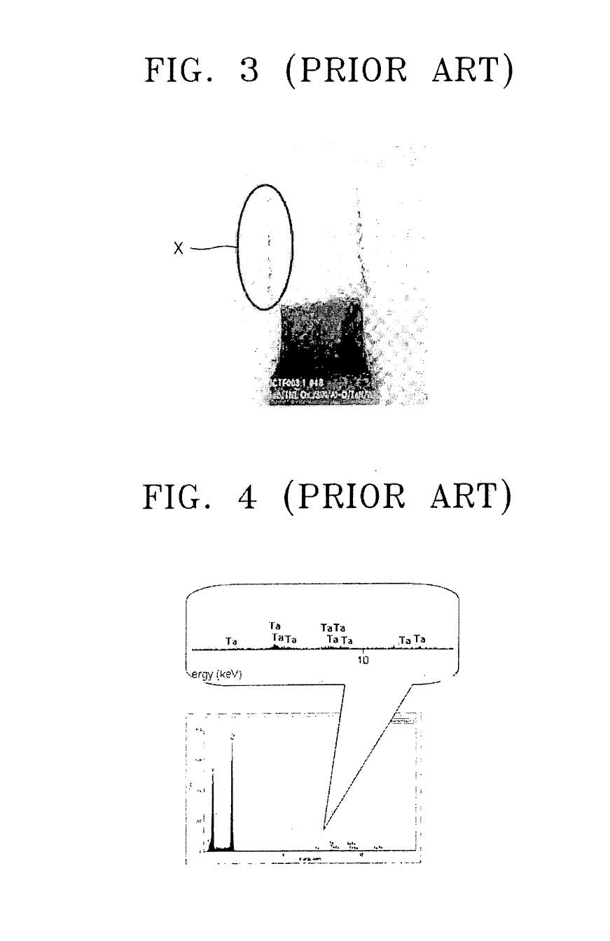

FIGS. 5A through 5E are SEM images showing products after cleaning with various substrate cleaning compositions according to embodiments of the invention;

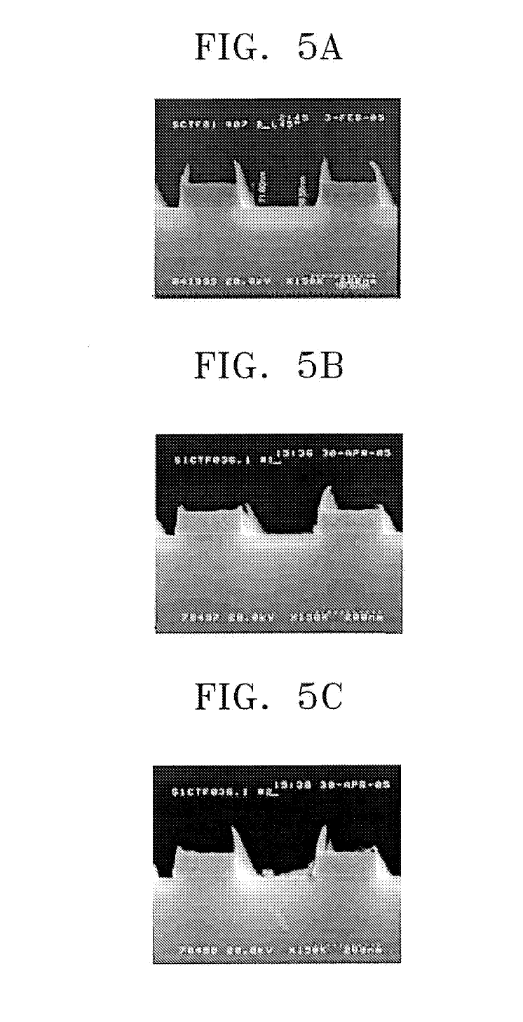

FIG. 6 is an SEM image showing a product after cleaning with a mixture of the substrate cleaning composition of FIG. 5E and acetic acid;

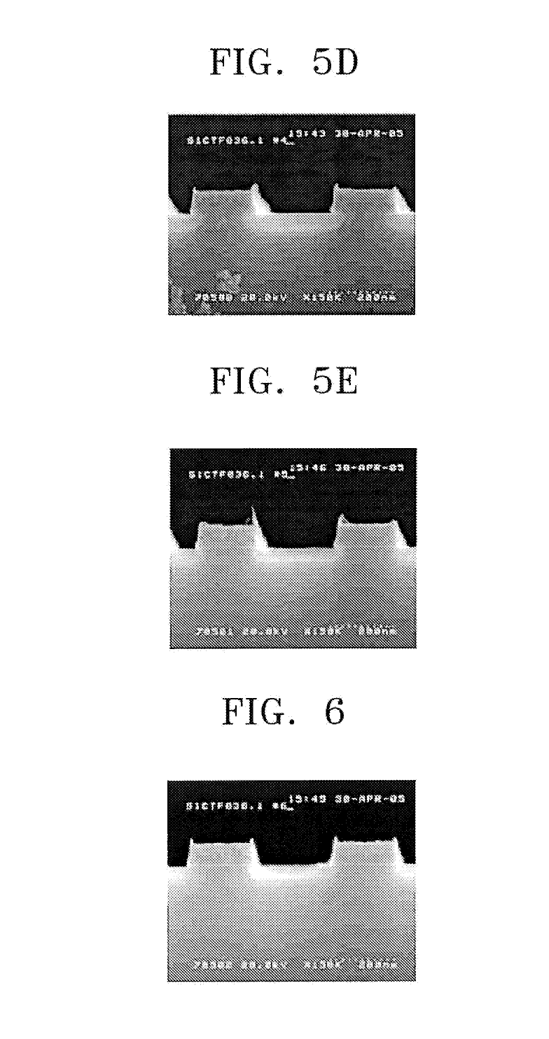

FIGS. 7A through 7C are SEM images showing products after cleaning with various substrate cleaning compositions according to embodiments of the invention;

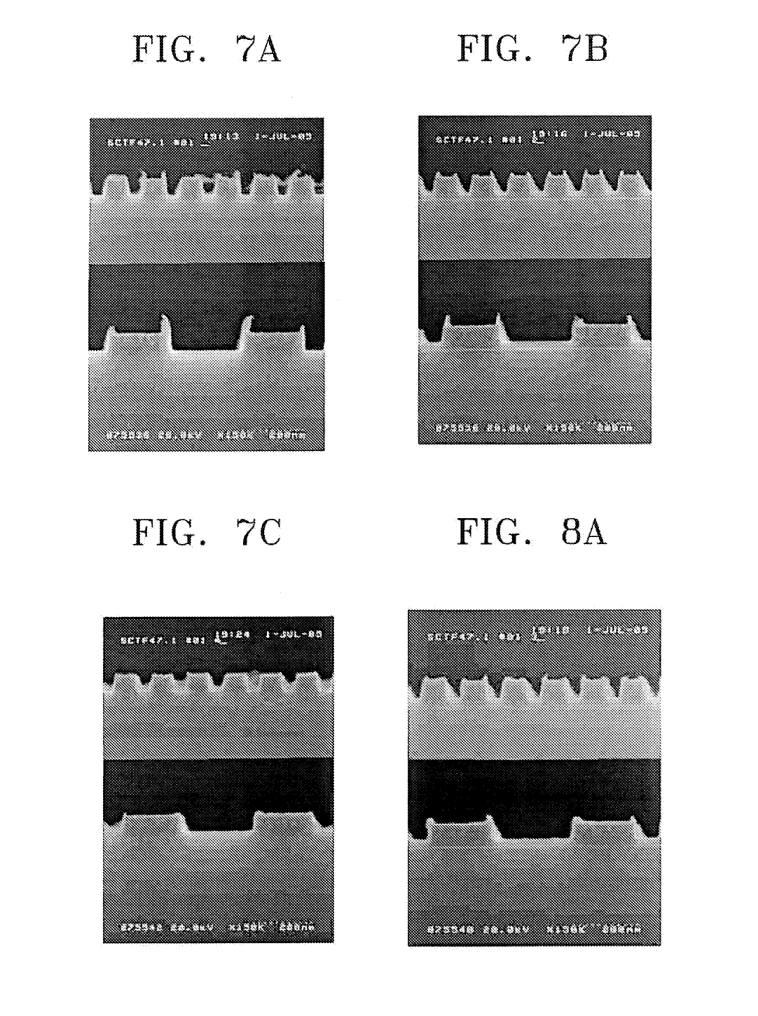

FIGS. 8A through 8C are SEM images showing products after cleaning with various substrate cleaning compositions according to embodiments of the invention;

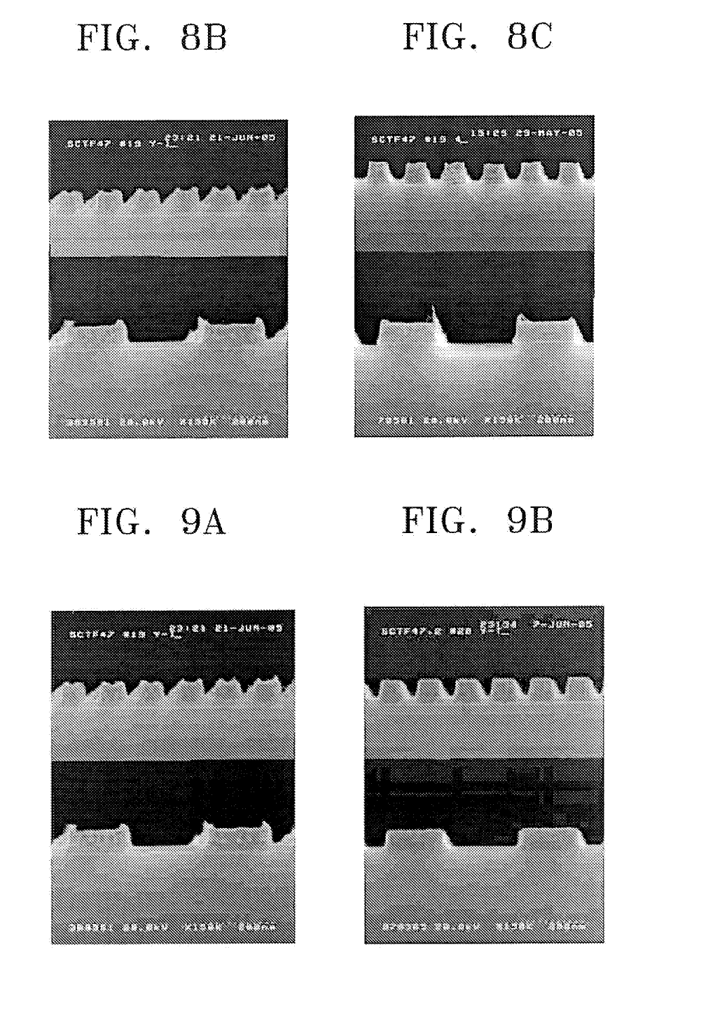

FIGS. 9A through 9D are SEM images showing products after cleaning with various substrate cleaning compositions according to embodiments of the invention;

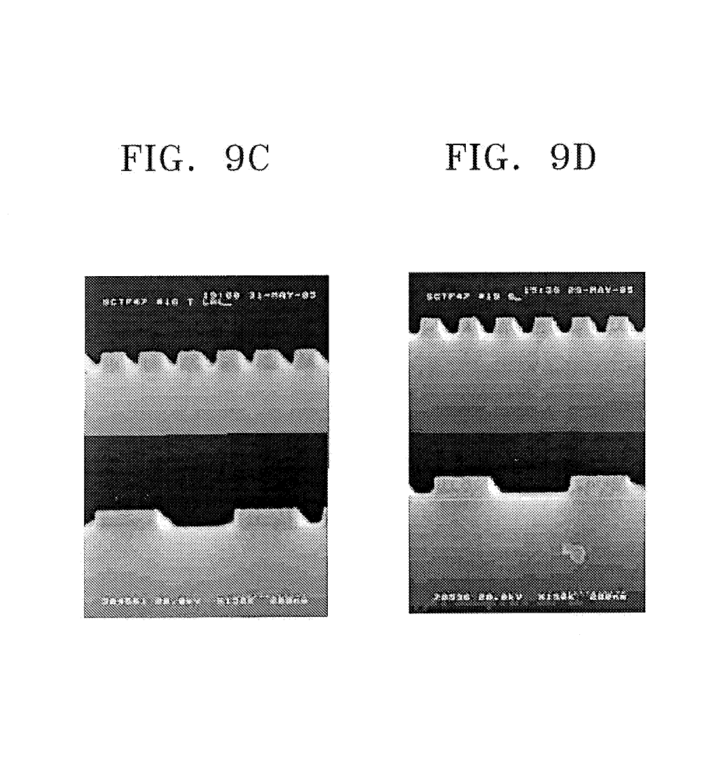

FIGS. 10A through 10C are SEM images showing products after cleaning with various substrate cleaning compositions according to embodiments of the invention;

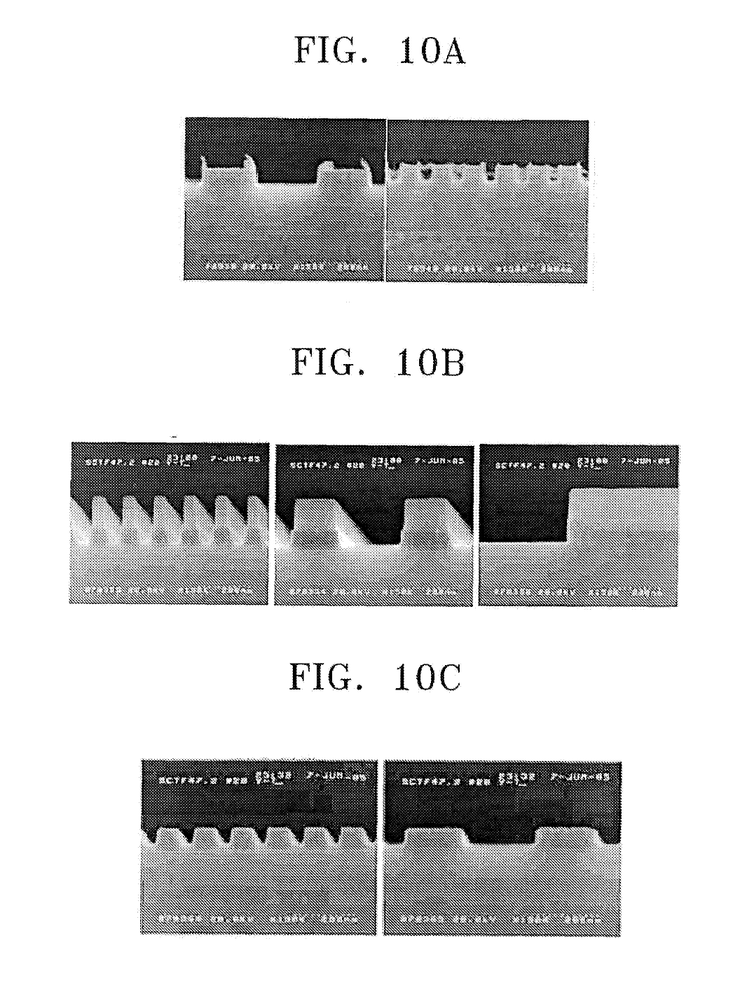

FIGS. 11A through 11C are SEM images showing products after cleaning with various substrate cleaning compositions according to embodiments of the invention;

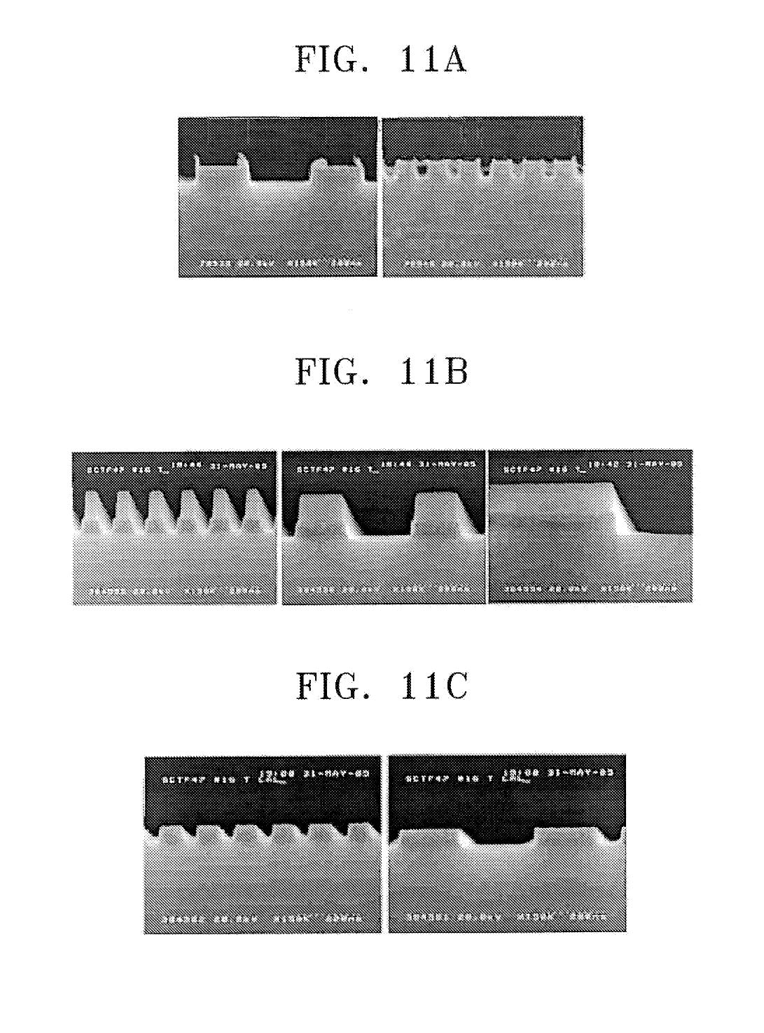

FIG. 12 is a graph illustrating the threshold voltage distribution of a gate structure with respect to the cleaning process using a substrate cleaning composition according to an embodiment of the invention; and

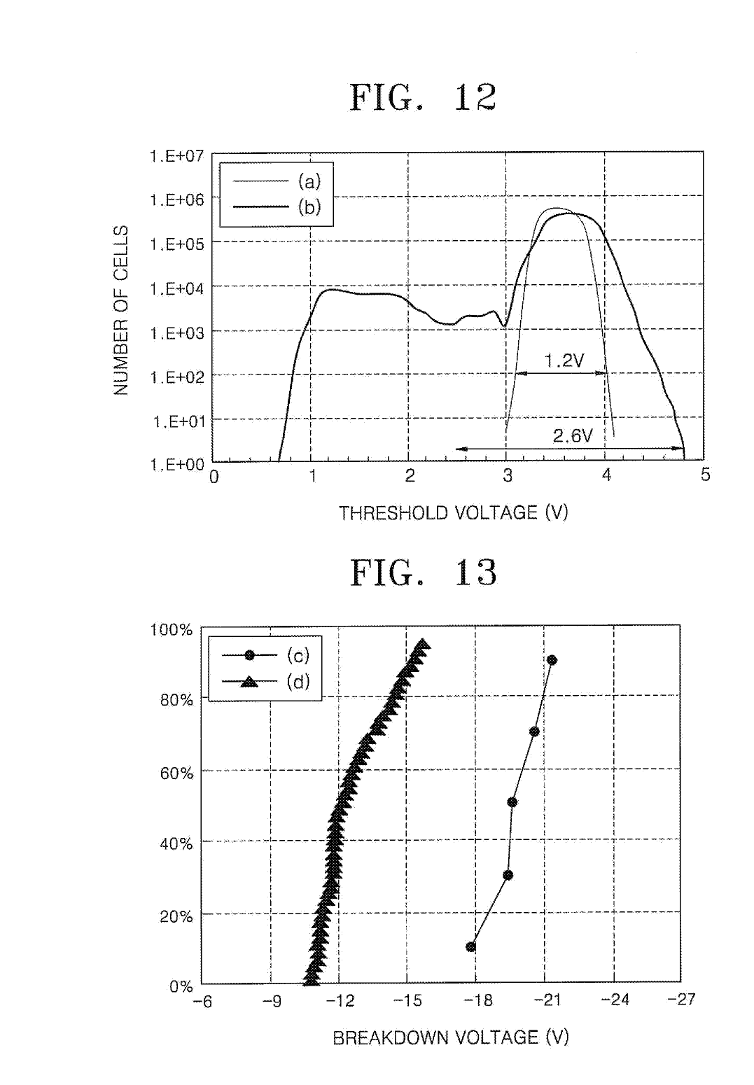

FIG. 13 is a graph illustrating the breakdown voltage distribution of a gate structure with respect to the cleaning process using a substrate cleaning composition according to an embodiment of the invention.

### DESCRIPTION OF EXEMPLARY EMBODIMENTS

Embodiments of the invention will be described with reference to the accompanying drawings. The invention may, however, be embodied in many different forms and should not be construed as being limited to only the embodiments set forth herein. Rather, the illustrated embodiments are provided as teaching examples. In the drawings, like reference numerals denote like elements.

FIGS. 1A through 1D are cross-sectional views illustrating a method of forming a gate structure according to an embodiment of the invention. In the illustrated embodiment, the gate structure is formed from a TaN metal layer. This is, however, only one selected example of the present invention and its use. Referring to FIG. 1A, a gate insulation layer 105, a TaN metal layer 110, and a hard mask 115 are sequentially stacked on a substrate 100. Gate insulation layer 105, TaN metal layer 110, and hard mask 115 may be conventionally formed using a deposition method such as chemical vapor deposition (CVD) or physical vapor deposition (PVD). Gate insulation layer 105 may be an oxide layer. Hard mask 115 may be formed of an insulator, for example, a plasma enhanced oxide (PEOX). A photoresist pattern 120 is formed on hard mask 115 to define the shape of a gate structure.

Referring to FIG. 1B, hard mask 115 is etched using photoresist pattern 120, and thereafter photoresist pattern 120 is removed. The etching is performed using a conventional method such as dry etching or wet etching.

Referring to FIG. 1C, TaN metal layer 110 and gate insulation layer 105 are sequentially dry etched using hard mask 115 as an etch mask. The reactive gas used in the dry etching process may be C₄F₆, O₂, Ar, or a mixture thereof. Polymer by-products 125 are routinely produced by the etching dry etching process and often remain on the side walls of hard mask 115. Metal ions liberated from TaN metal layer 110 by the etching process typically combined with organic materials to form polymer by-products 125. In addition, polymer by-products 125 may include residue generated by the removal of photoresist pattern 120.

Referring to FIG. 1D, polymer by-product 125 is cleaned using a substrate cleaning composition 130 to form a desired gate structure.

In one embodiment, substrate cleaning composition 130 comprises a fluoride compound, an inorganic acid, and deionized water. The concentration of the fluoride compound ranges between about 0.001 and 10.0 wt %, and the concentration of the inorganic acid ranges between about 3 and 20 wt %, respectively based on the total weight of substrate cleaning composition 130. The fluoride compound may comprise one or more of HF, NH₄F, and a combination thereof, and in one particular embodiment preferably comprises HF. The inorganic acid may comprise one or more of HNO₃, HCl, HCIO₄, H₂SO₄, H₅IO₆, and a combination thereof, and in one particular embodiment preferably comprise HNO₃. In one particular embodiment, substrate cleaning composition 130 comprises about 0.35 wt % of HF and about 5.0 wt % of HNO₃, and the remainder of substrate cleaning composition 130 is deionized water.

Substrate cleaning composition 130 may further comprise one or more of acetic acid, palmitic acid, oxalic acid, tartaric acid, and a combination thereof. In one particular embodiment, substrate cleaning composition 130 further comprises acetic acid. In this embodiment, the concentration of the organic acid will typically be less than about 50 wt % based on the total weight of substrate cleaning composition 130. For example, excellent results have been achieved by the use of a substrate cleaning composition 130 comprising about 1.0 wt % of HF, about 1.0 wt % of HNO₃, and about 44.0 wt % of acetic acid, and the remainder comprising deionized water.

Substrate cleaning composition 130 may further comprise a surfactant and a chelating agent. The concentrations of the surfactant and the chelating agent may be respectively less than 10 wt % based on the total weight of substrate cleaning composition 130. For example, in one particular embodiment, substrate cleaning composition 130 comprises about 0.35 wt % of HF, about 5.0 wt % of HNO₃, about 3.0 wt % of a mixture of the surfactant and the chelating agent, and the remainder comprising deionized water.

The surfactant provides protection for the oxide layer and may be an ethylene oxide-based compound of which both end groups are hydroxide groups. For example, the surfactant may be one or more of ethylene glycol, propylene glycol, ethylene oxide, monoethylene glycol, diethylene glycol, triethylene glycol, propylene oxide, 1,2-propylene glycol, dipropylene glycol, tripropylene glycol, 1,2-butylene oxide, and a combination thereof.

The chelating agent removes separated metal ions and protects the residual metal layer after etching. For example, the chelating agent may be an amine-based compound comprising one or more of a C₁ to C₁₀ alkyl group, monoethanolamine, diethanolamine, triethanolamine, diethylenetriamine, and a combination thereof. The chelating agent may comprise an amine carboxylic acid ligand such as diethylenetriamine pentaacetic acid. Alternatively the chelating agent may comprise an amino acid such as glycine, alanine, valine, leucine, isoleucine, serine, threonine, tyrosine, phenylalanine, tryptophane, methionine, cystine, proline, sulphamin acid, and hydroxyproline.

Substrate cleaning composition 130 may further comprise other conventionally used additive(s) such as a corrosion inhibitor in addition to or in the alternative to the surfactant and chelating agent. The concentration of such additives will typically be less than about 10% based on the total weight of the substrate cleaning composition.

When a cleaning process is performed using the substrate cleaning composition of the present invention, the cleaning process may be performed either by a spraying method or a dipping method. In many embodiments, the cleaning process will be performed at a temperature ranging between about 30 and 100° C.

Using the foregoing teachings, a gate structure comprising a metal layer, such as a TaN metal layer, and well adapted for use within a specific semiconductor device, such as a semiconductor memory device, may be effectively formed.

FIGS. 2A through 2D are cross-sectional views illustrating a method of forming a gate structure according to another embodiment of the invention. In the illustrated embodiment, a method of forming a gate structure comprising a TANOS structure within a nonvolatile memory device is described. The TANOS structure comprises an aluminum oxide-nitride-oxide (ANO) structure that functions as a floating gate adapted to store charge. A corresponding control gate adapted to control the development of charge to/from the ANO structure comprises a metal layer made (e.g.,) of TaN. The TaN material has a high work function and therefore provides an easily controlled threshold voltage. In the illustrated example that follows, it is assumed that a tungsten (W) metal layer is formed on the TaN metal layer to maximize the charge development rate of the gate structure.

Referring to FIG. 2A, a tunnel oxide layer 205, a nitride layer 210 adapted to trap charge, and an aluminum oxide layer 215 adapted for use as a charge protecting layer are sequentially stacked on a semiconductor substrate 200. A TaN metal layer 220 and W metal layer 225 are formed on aluminum oxide layer 215. In order to easily form W metal layer 225 on TaN metal layer 220, a W metal thin film is formed and plasma-treated using nitrogen gas, and then the W is deposited to a predetermined thickness. Accordingly, W metal layer 225 may be a double metal layer of tungsten nitride (WN) and W.

A hard mask 230 made (e.g.,) of PEOX is then formed on W metal layer 225. Tunnel oxide layer 205, nitride layer 210, aluminum oxide layer 215, TaN metal layer 220, W metal layer 225, and hard mask 230 may be conventionally formed using methods such as CVD or PVD. A photoresist pattern 235 defining the gate structure is then formed on hard mask 230.

Referring to FIG. 2B, hard mask 230 is etched using photoresist pattern 235 as an etch mask, and then photoresist pattern 235 is removed using a conventional ashing and stripping process.

Referring to FIG. 2C, W metal layer 225, TaN metal layer 220, aluminum oxide layer 215, nitride layer 210, and tunnel oxide layer 205 are sequentially etched using hard mask 230 as an etch mask, thereby forming an ANO structure and a control gate. TaN metal layer 220 and W metal layer 225 may be dry etched. In the illustrated embodiment, the metal layers forming the control gate and the ANO structure are simultaneously etched using hard mask 230, but this need not be the case. As a by-product of dry etching of TaN metal layer 220 and W metal layer 225, hard polymer by-products 240 commonly form on the side walls of hard mask 230. Hard polymer by-products 240 may comprise metal compositions that are difficult for conventional cleaning solutions to remove. This is particularly true for Ta. In addition, polymer by-products 240 may comprise residues generated when photoresist 235 is removed.

Referring to FIG. 2D, hard polymer by-products 240 may be removed using a substrate cleaning composition 250. Substrate cleaning composition 250 and related cleaning processes may be similar to those described above with respect to FIG. 1D. In this manner, a gate structure well adapted for use within a nonvolatile memory device having a TANOS structure may be formed.

Hereinafter, experimental examples (e.g., gate structures and the like) obtained using various substrate cleaning compositions according to embodiments of the invention will be described. Additionally, electric characteristics for the experimental examples will be described. The example numbers that follow are used merely to identify respective experimental examples. No other limitation or significance should be attached to these example numbers.

### Experimental Example One

In this example, the effectiveness of a conventional substrate cleaning composition in cleaning hard polymer by-products is evaluated for comparative purposes.

Samples used in experimental example 1 were manufactured as follows. A tunnel oxide layer, a nitride layer, an aluminum oxide layer, a TaN metal layer, a W/WN metal layer, and a hard mask made of PEOX were formed on a silicon substrate. Then, the W/WN metal layer, the TaN metal layer, and the aluminum oxide layer were dry etched using the hard mask as an etch mask. The etching gas was a conventional etching gas such as a mixture of C₄F₆, O₂, N₂, and Ar. The sample was cleaned using EKC 245, which is a commercially available substrate cleaning composition.

FIG. 3 is a scanning electron microscope (SEM) image of a product cleaned by EKC 245. Referring to FIG. 3, a hard polymer by-product is shown in region “X”, e.g., on the side wall of the patterned hard mask layer.

FIG. 4 is a graph from an energy dispersive X-ray spectroscopy (EDXS) illustrating the composition of the hard polymer by-product shown in FIG. 3. Referring to FIG. 4, the main composition of the hard polymer by-product “X” includes Ta.

### Experimental Example Two

In this example, the effectiveness of various substrate cleaning compositions was evaluated using multiple samples prepared as described above with reference to Experimental Example One. These samples were variously treated using different substrate cleaning compositions.

A sample reference group 1 (a control reference) was not cleaned after dry etching. A sample reference group 2 was cleaned using a substrate cleaning composition comprising HF, H₂O₂, and deionized water with a weight ratio of 1:20:80 for 2 minutes. A sample reference group 3 was cleaned using a substrate cleaning composition comprising HF, CH₃COOOH(PAA), and deionized water with a weight ratio of 1:10:80 for 2 minutes. A sample reference group 4 was cleaned using a substrate cleaning composition comprising HF and deionized water with a weight ratio of 4:96 for 2 minutes. A sample reference group 5 was cleaned using a substrate cleaning composition including HF, HNO₃, and deionized water with a weight ratio of 1:5:94 for 2 minutes.

The sample references and control reference were wet etched for 25 seconds using etchant (LAL) after cleaning, the hard masks thereof were removed, and then polymer by-products disposed on side walls of the hard mask were evaluated from corresponding SEM images.

FIGS. 5A through 5E are SEM images showing example products after cleaning with various substrate cleaning compositions according to embodiment(s) of the invention. Referring to FIG. 5A, the results of sample reference group 1, shows an initial state including a residual hard polymer by-product. Referring to FIGS. 5B and 5C, the results of sample reference groups 2 and 3 are shown with hard polymer by-products not completely removed. Referring to FIG. 5D, the results of sample reference group 4 show that the hard polymer by-products have been completely removed, other layers, not to be removed (e.g., the oxide layer), were also removed. Referring to FIG. 5E, the results of sample reference group 5, using an exemplary substrate cleaning composition according to the invention, show that the hard polymer by-products are completely removed, but other layers remained as intended. Thus, according to the illustrated results and in relation to the illustrated examples, a substrate cleaning composition according to one embodiment of the invention, comprising deionized water, a fluoride compound such as HF, and an inorganic acid such as HNO₃ produces favorable results in removing hard polymer by-products from the exemplary gate structure, including a Ta layer.

### Experimental Example Three

In this example 4, based on the results of Experimental Example Two above, the effectiveness of a substrate cleaning composition comprising HF, HNO₃, deionized water, and further comprising CH₃COOH was evaluated. A sample reference group was cleaned using a substrate cleaning composition comprising HF, HNO₃, CH₃COOH, and deionized water with a weight ratio of 1:5:44:50 at 25° C. for 2 minutes. Similarly prepared samples and exemplary processes were used described above.

Referring to FIG. 6, the substrate cleaning composition comprising HNO₃, deionized water, and, further comprising an organic acid, (e.g., CH₃COOH), yielded, very favorable results in cleaning hard polymer by-products.

### Experimental Example Four

In this example, the effectiveness of substrate cleaning compositions in cleaning hard polymer by-products as a function of the concentration of HNO₃ was evaluated. Samples were cleaned using a first substrate cleaning composition comprising 0.5 wt % of HF and 1.0 wt % of HNO₃, a second substrate cleaning composition comprising 0.5 wt % of HF and 10.0 wt % of HNO₃, and a third substrate cleaning composition comprising 0.5 wt % of HF and 18.0 wt % of HNO₃, with the remainder of the respective substrate cleaning compositions being deionized water. Each of the substrate cleaning compositions was applied to about 1 minute at a temperature of 25° C. Similarly prepared samples and exemplary processes were used, as described above

FIGS. 7A through 7C show the results of these various applications. Referring to FIGS. 7A through 7C, the substrate cleaning composition comprising 10 or 18 wt % of HNO₃ exhibited the best overall effectiveness in cleaning hard polymer by-products. Accordingly, many embodiments of the substrate cleaning composition according to the invention will favorably include about 3 to 20 wt % of an inorganic acid such as HNO₃.

### Experimental Example Five

In this example, the effectiveness of substrate cleaning compositions in cleaning hard polymer by-products as a function of the concentration of HF was evaluated. Samples were cleaned using a first substrate cleaning composition comprising 0.1 wt % of HF and 5.0 wt % of HNO₃, a second substrate cleaning composition comprising 0.35 wt % of HF and 5.0 wt % of HNO₃, and a third substrate cleaning composition comprising 1.0 wt % of HF and 5.0 wt % of HNO₃, with the remainder of each respective substrate cleaning composition being deionized water. Here again, each of the substrate cleaning compositions was applied to about 1 minute at a temperature of 25° C. Similarly prepared samples and exemplary processes were used, as described above.

FIGS. 8A through 8C show the results of these various applications. Referring to FIGS. 8A through 8C, the effectiveness of the various substrate cleaning compositions was about the same relative to concentration of HF. However, when the concentration of a fluoride compound (e.g., HF) in the substrate cleaning composition was increased, material layers other than the hard polymer by-products were etched. Therefore, in many embodiments of the invention, the concentration of fluoride compound in the substrate cleaning composition will favorably range from between 0.001 to 10.0 wt %.

### Experimental Example Six

In this example, the effectiveness of a substrate cleaning composition in cleaning hard polymer by-products as a function of collaterally occurring etching of other layers with respect to temperature was evaluated. The exemplary substrate cleaning composition used in this example comprises 0.35 wt % of HF, 5.0 wt % of HNO₃, and 3 wt % of additives, with the remainder being deionized water. The exemplary substrate cleaning composition was applied for about 1 minute at temperatures of 25° C., 40° C., 50° C., and 60° C. Similarly prepared samples and exemplary processes were used, as described above.

FIGS. 9A through 9D show the results of these temperature varying applications. Referring to FIGS. 9A through 9D, the applications of the cleaning process performed at 40° C., 50° C., and 60° C. were more effective than the cleaning process performed at 25° C. However, when the temperature of the cleaning process was much above 100° C., the possibility of unexpected defects rises. Accordingly, in many embodiments, the cleaning process using the substrate cleaning composition according to the present invention will be favorably performed at a temperature ranging from about 30 to 100° C.

In addition, the degree to which other layers were etched under the influence of the substrate cleaning composition according to the present with respect to temperature was also evaluated. Referring to Table 1, when the temperature was 50 or 60° C., thermal oxide layers, polysilicon layers, PEOX layers, and TaN layers were etched to a greater degree. Accordingly, when temperature was 40° C., the hard polymer by-products were completely cleaned while the other layers were etched to a lesser degree.

TABLE 1

| | Amount of etching layers | | | | | | | |
|---|---|---|---|---|---|---|---|---|
| Conditions | Thermal | Polysilicon | | PEOX | | | | |
| of cleaning | oxide | layer | PEOX | undercut | | | | |
| process | layer | (after | layer | (V-SEM) | | W | TaN | Others |
| 25° C. | 5 Å | 4 Å | 65 Å | <20 | Å | — | 2 Å | |
| 1 minute | | | | | | | | |
| 40° C. | 7 Å | 5.5 Å | 133 Å | 90 to 110 | Å | — | 4 Å | Optimum |
| 1 minute | | | | | | | | condition |
| 50° C. | 10 Å | 7 Å | 140 Å | 90 to 110 | Å | — | 7 Å | |
| 1 minute | | | | | | | | |
| 60° C. | 15 Å | 9 Å | 148 Å | 90 to 110 | Å | — | 10 Å | |
| 1 minute | | | | | | | | |

### Experimental Example Seven

In this example, the effectiveness (e.g., uniformity) of various substrate cleaning compositions on the removal of hard polymer by-products at a wafer level was evaluated. The exemplary substrate cleaning composition used in this example comprises 35 wt % of HF, 5.0 wt % of HNO₃, and 3 wt % of additives, and the remainder deionized water.

Similarly prepared samples and exemplary processes were used, as described above. However, the samples were not cleaned and the hard mask thereof was removed using an etchant (LAL). That is, samples in a first group were cleaned at 40° C. for 1 minute using the substrate cleaning composition according to the embodiment of the present invention, and the hard mask was not removed. Samples in a second group were wet etched using an etchant (LAL) to remove the hard mask.

The results were evaluated using SEM images, and FIGS. 10A through 10C show the results. Referring to FIGS. 10A through 10C, when the cleaning process was performed using the substrate cleaning composition according to the embodiment of the present invention before performing a cleaning process for the entire wafer, the cleaning power of substrate cleaning compositions for polymer by-products was excellent.

### Experimental Example Eight

In this example, the effectiveness of substrate cleaning compositions in cleaning hard polymer by-products at a wafer level was further evaluated. Except for a cleaning process temperature of 50° C., other conditions were the same as in Experimental Example Seven.

FIGS. 11A through 11C show the corresponding results. Referring to FIGS. 11A through 11C, when the cleaning process was performed at 50° C. using the substrate cleaning composition according to the embodiment of the present invention before performing a cleaning process for the entire wafer, the cleaning power of substrate cleaning compositions for polymer by-products was excellent.

### Experimental Example Nine

In this example, changes in the gate threshold voltage were evaluated in relation to whether or not the cleaning process using the substrate cleaning composition according to the embodiment of the present invention was performed. Samples used in this example were manufactured as follows. A tunnel oxide layer, a nitride layer, an aluminum oxide layer, a TaN metal layer, a W/WN metal layer, and a hard mask made of PEOX were formed on a silicon substrate. Then, the W/WN metal layer, the TaN metal layer, the aluminum oxide layer, the nitride layer, the tunnel oxide layer were dry etched using the hard mask as an etch mask. The etching gas was a conventional etching gas such as a mixture of C₄F₆, O₂, N₂, and Ar.

The samples in the reference group were not cleaned to form a gate of a nonvolatile memory device. The samples in the experimental group were cleaned at 50° C. for 1 minute using the substrate cleaning composition according to the embodiment of the present invention, and then a gate of a nonvolatile memory device was formed. The exemplary substrate cleaning composition used comprises 0.35 wt % of HF, 5.0 wt % of HNO₃, and 3 wt % of additives, and the remainder deionized water. (As with all of the foregoing examples, the wt % represents a weight percent of each composition in the substrate cleaning compositions based on the total weight of the substrate cleaning composition). Gate threshold voltages for the reference group and the experiment group were then measured.

In FIG. 12, line (a) shows the result of the experimental group and line (b) shows the result of the reference group. Referring to FIG. 12, when the cleaning process was not performed, the distribution of the threshold voltage was poor because of the generation of leakage current due to the polymer by-products. Therefore, when the cleaning process is performed using the substrate cleaning composition of the present invention, a gate having a uniform threshold voltage can be formed.

### Experimental Example Ten

In this example, changes in a gate breakdown voltage were evaluated in relation to whether or not the cleaning process using the substrate cleaning composition according to the embodiment of the present invention was performed.

The processes of manufacturing and cleaning the samples were the same as those in Experimental Example Nine. The breakdown voltages of a reference group which was not cleaned and of a experimental group which was cleaned were then measured.

In FIG. 13, line (c) shows the result of the experimental group and line (d) shows the result of the reference group. Referring to FIG. 13, the breakdown voltage when the cleaning process was performed is much higher than that when the cleaning process was not performed. The cleaning process selectively removes the polymer by-product, such that the generation of the leakage current in the gate can be prevented. Accordingly, the gate can sustain high voltage. Therefore, when the cleaning process is performed using the substrate cleaning composition of the present invention, a gate having a high breakdown voltage can be formed.

A substrate cleaning composition according to embodiments of the invention comprise a fluoride compound, an inorganic acid, and deionized water, thereby selectively removing polymer by-products produced by dry etching a metal layer. That is, the substrate cleaning composition is favorably effective in the removal of hard polymer by-products, but has a poor etching power relative to other layers. In particular, the substrate cleaning composition has a favorable selective cleaning effectiveness relative to hard polymer by-products comprising Ta, which cannot be easily removed using conventional cleaning solutions. In addition, embodiments of the substrate cleaning composition may further comprise an organic acid such as an acetic acid, a surfactant, a chelating agent, thereby increasing the selective cleaning effectiveness of the composition to remove hard polymer by-products.

The present invention provides a method of forming a gate structure for a specific semiconductor device by, in part, performing a cleaning process using the inventive substrate cleaning composition. The cleaning process using the substrate cleaning composition according to embodiments of the invention selectively removes hard polymer by-products, but not other layers used to form the gate structure, thereby preventing the generation of leakage current. Accordingly, a semiconductor device gate structure having favorable electric characteristics may be formed.

While the present invention has been particularly shown and described with reference to exemplary embodiments thereof, it will be understood by those of ordinary skill in the art that various changes in form and details may be made therein without departing from the scope of the invention as defined by the following claims.

What is claimed is:

1. A method of forming a gate structure adapted for use in a semiconductor device, the method comprising:
forming a metal layer;
forming a hard mask on the metal layer;
etching the metal layer using the hard mask as an etch mask; and
cleaning the resultant structure with a substrate cleaning composition comprising a fluoride compound, an inorganic acid, and deionized water.

2. The method of claim 1, further comprising:
prior to forming the metal layer, forming a gate insulation layer, such that the metal layer is formed on the gate insulation layer; and
etching the gate insulation layer using the hard mask as an etch mask prior to cleaning the resultant structure.

3. The method of claim 1, wherein the metal layer comprises tantalum.

4. The method of claim 3, further comprising before the forming of the metal layer:
forming a tunnel oxide layer on a substrate, the tunnel oxide layer being adapted to pass charge to/from the substrate;
forming a nitride charge trapping layer on the tunnel oxide layer;
forming a charge protecting layer comprising aluminum oxide on the charge trapping layer; and,
forming a tantalum-aluminum oxide-nitride-oxide-silicon (TANOS) structure.

5. The method of claim 1, wherein the hard mask comprises a plasma enhanced oxide (PEOX).

6. The method of claim 1, wherein etching of the metal layer comprises performing a dry etch on the metal layer.

7. The method of claim 1, wherein the fluoride compound comprises at least one of HF, and NH₄F.

8. The method of claim 1, wherein the inorganic acid comprises at least one selected from a group consisting of HNO₃, HCl, HCIO₄, H₂SO₄, and H₅IO₆.

9. The method of claim 1, wherein substrate cleaning composition further comprises at least one of an acetic acid, a surfactant, and a chelating agent.

10. The method of claim 1, wherein cleaning the resultant structure is performed at a temperature ranging from between about 30 to 100° C.

11. The method of claim 1, wherein cleaning the resultant structure is performed by either a spraying method or a dipping method.
